(19) United States
(12) Patent Application Publication
(10) Pub. No.: US 2020/0043877 A1
(43) Pub. Date: Feb. 6, 2020

(54) SEMICONDUCTOR DEVICE

(71) Applicant: RENESAS ELECTRONICS CORPORATION, Tokyo (JP)

(72) Inventors: Kentaro SAITO, Tokyo (JP); Takashi MORIYAMA, Tokyo (JP); Yoshinori DEGUCHI, Tokyo (JP)

(21) Appl. No.: 16/460,552

(22) Filed: Jul. 2, 2019

(30) Foreign Application Priority Data
Jul. 31, 2018 (JP) 2018-143294

(51) Int. Cl. H01L 23/00; H01L 23/522

(52) U.S. Cl. CPC H01L 24/06; H01L 23/5226; H01L 24/05; H01L 2224/04042; H01L 2224/0603; H01L 2224/05552; H01L 2224/05557; H01L 2224/06051; H01L 2224/06135

(57) ABSTRACT

A semiconductor device includes semiconductor substrate having outer peripheral sides in plan view, and at least a pair of first bonding pad and second bonding pad formed over the semiconductor substrate. The second bonding pad has a shape obtained by rotating the first bonding pad by 180 degrees in plan view. The first bonding pad and the second bonding pad are arranged so as to face each other in a first direction crossing the outer peripheral side. The first bonding pad has a first portion and a second portion of rectangular shape in the second direction along the outer peripheral side. A width of the first portion in the first direction is greater than a width of the second portion in the first direction.

### CROSS-REFERENCE TO RELATED APPLICATIONS

The disclosure of Japanese Patent Application No.2018-143294 filed on Jul. 31, 2018 including the specification, drawings and abstract is incorporated herein by reference in its entirety.

### BACKGROUND

The present invention relates to a semiconductor device.

Conventionally, a semiconductor device described in Japanese unexamined Patent Application publication No. 2010-272622 (patent document 1) has been known. The semiconductor device described in the patent document 1 includes a substrate and a plurality of bonding pads formed over a substrate.

The bonding pad is divided into a probe region and a wire bonding region in plan view. The probe region is a region in which a probe for inspection contacts. The wire bonding region is a region for bonding a bonding wire. The probe region and the wire bonding region are arranged along a direction crossing the outer peripheral side of the substrate.

The bonding pads are arranged along a second direction crossing the first direction. A distance is provided between two bonding pads arranged adjacent to each other in the second direction.

### SUMMARY

In the semiconductor device described in the patent document 1, there is room for improvement in the width required to form the bonding pads in the second direction due to the distance between the two bonding pads arranged adjacent to each other in the second direction.

Other objects and novel features will be apparent from the description of this specification and the accompanying drawings.

A semiconductor device according to the embodiments includes a semiconductor substrate having an outer peripheral side in plan view, and a pair of first bonding pad and second bonding pad formed over the semiconductor substrate. The second bonding pad has a shape obtained by rotating the first bonding pad by 180 degrees in plan view. The first bonding pad and the second bonding pad are arranged so as to face each other in a first direction crossing the outer peripheral side. The first bonding pad has a first portion and a second portion of rectangular shape in a second direction along the outer peripheral side. A width of the first portion in the first direction is greater than a width of the second portion in the first direction.

According to the semiconductor device of the embodiments, the width required to form bonding pads in the direction along the outer peripheral side of the semiconductor substrate can be reduced.

### BRIEF DESCRIPTION OF THE DRAWINGS

FIG. 1 is a top view of a semiconductor device according to first embodiment.

FIG. 2 is an enlarged top view of the semiconductor device according the first embodiment.

FIG. 3 is an enlarged top view of a bonding pad BP1 in the semiconductor device according to the first embodiment.

FIG. 4 is a cross-sectional view of the semiconductor device according to the first embodiment.

FIG. 5 is a cross-sectional view at V-V in FIG. 3.

FIG. 6 is a step chart showing the manufacturing method of the semiconductor device according to the first embodiment.

FIG. 7 is a cross-sectional view of the semiconductor device according to the first embodiment after the front end step S1.

FIG. 8 is a cross-sectional view of the semiconductor device according to the first embodiment after the pre-metal insulating film forming step S21.

FIG. 9 is a cross-sectional view of the semiconductor device according to the first embodiment after the contact plug forming step S22.

FIG. 10 is a cross-sectional view of the semiconductor device according to the first embodiment after the first interlayer insulating film forming step S23.

FIG. 11 is a cross-sectional view of the semiconductor device according to the first embodiment after the first wiring forming step S24.

FIG. 12 is a cross-sectional view of the semiconductor device according to the first embodiment after the second interlayer insulating film forming step S25.

FIG. 13 is a cross-sectional view of the semiconductor device according to the first embodiment after the second wiring forming step S26.

FIG. 14 is a cross-sectional view of the semiconductor device according to the first embodiment after the third interlayer insulating film forming step S27.

FIG. 15 is a cross-sectional view of the semiconductor device according to the first embodiment after the via plug forming step S28.

FIG. 16 is a cross-sectional view of the semiconductor device according to the first embodiment after the bonding pad forming step S29.

FIG. 17 is a top view of a semiconductor device according to a comparative example.

FIG. 18 is an enlarged top view of a semiconductor device according to the comparative example.

FIG. 19 is an enlarged top view of a semiconductor device according to second embodiment.

FIG. 20 is an enlarged top view of the semiconductor device according to the comparative example in which power supply wirings PL_{VDD} are also shown.

FIG. 21 is an enlarged top view of the semiconductor device according to the second embodiment in which power supply wirings PL_{VDD} are also shown.

FIG. 22 is an enlarged top view of a semiconductor device according third embodiment.

FIG. 23 is an enlarged top view of a semiconductor device according to fourth embodiment.

FIG. 24 is an enlarged top view of a semiconductor device according to first modification of the fourth embodiment.

FIG. 25 is an enlarged top view of a semiconductor device according to second modification of the fourth embodiment.

### DETAILED DESCRIPTION

The details of the embodiments will be described with reference to the drawings. In the following drawings, the same or corresponding parts are denoted by the same reference characters, and the description thereof will not be repeated. At least some of the embodiments described below may be optionally combined.

### First Embodiment

Hereinafter, a configuration of a semiconductor device according to first embodiment will be described.

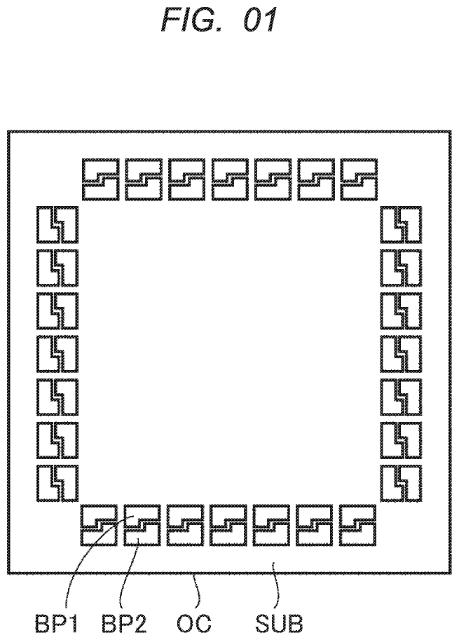

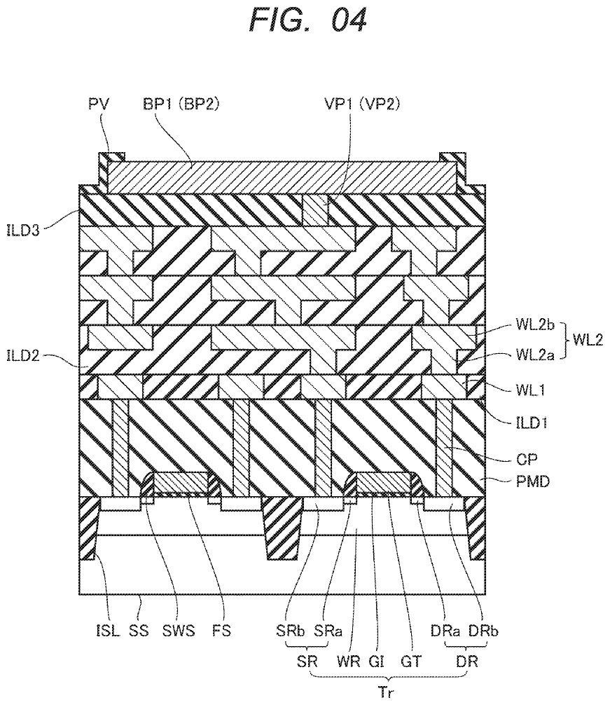

As shown in FIGS. 1, 2, 3, and 4, the semiconductor device according to the first embodiment includes a semiconductor substrate SUB, a pair of bonding pad BP1 and bonding pad BP2. The number of bonding pads BP1 and the number of bonding pads BP2 to be paired may be plural. A plurality of pairs of bonding pads BP1 and bonding pads BP2 is arranged along a second direction DR2 described later.

The semiconductor device according to the first embodiment further includes gate dielectric films GI, gates GT, sidewall spacers SWS, element isolation films ISL, a pre-metal insulating film PMD, contact plugs CP, interlayer insulating films ILD1 to ILD3, wirings WL1 and wirings WL2, via plugs VP1 and via plugs VP2, and a passivation film PV.

The semiconductor substrate SUB is made of, for example, single-crystal silicon (Si). The semiconductor substrate SUB has a first surface FS and a second surface SS. The first surface FS and the second surface SS constitute a main surface of the semiconductor substrate SUB. The second surface SS is an opposite surface of the first surface FS. The semiconductor substrate SUB has outer peripheral sides OC in plan view (viewed from a direction orthogonal to the first surface FS). The outer peripheral sides OC are sides constituting an outer periphery of the semiconductor substrate SUB. Hereinafter, a direction crossing the outer peripheral side OC is referred to as a first direction DR1, and a direction along the outer peripheral side OC is referred to as a second direction DR2.

The semiconductor substrate SUB has source regions SR, drain regions DR, and well regions WR. Conductivity types of the source regions SR and the drain regions DR are first conductivity types. Conductivity types of the well regions WR are second conductivity types. The second conductivity type is the opposite conductivity type of the first conductivity type. For example, when the first conductivity type is n-type, the second conductivity type is p-type.

The source regions SR and the drain regions DR are formed in the first surface FS. The source region SR and the drain region DR is formed apart from each other.

The source region SR has a first portion SRa and a second portion SRb. The first portion SRa is located closer to the drain region DR side than the second portion SRb. The impurity concentration in the first portion SRa is lower than the impurity concentration in the second portion SRb. That is, the source region SR has a Lightly Doped Diffusion (LDD) structure.

The drain region DR has a first portion DRa and a second portion DRb. The first portion DRa is located closer to the source region SR side than the second portion DRb. The impurity concentration in the first portion DRa is lower than the impurity concentration in the second portion DRb. That is, the drain region DR has an LDD structure.

The well regions WR are formed in the first surface FS so as to surround the source regions SR and the drain regions DR. The well region WR has a portion (a channel region) sandwiched between the source region SR and the drain region DR in the first surface FS.

The gate dielectric film GI is made of, for example, silicon oxide (SiO₂). The gate dielectric film GI is formed on the first surface FS. More specifically, the gate dielectric film GI is formed on the channel region.

The gate GT is made of, for example, polycrystalline silicon doped with impurities. The gate GT is formed on the gate dielectric film GI. As a result, the gate GT faces the channel region while the gate GT is insulated from the channel region by the gate dielectric film GI.

The sidewall spacer SWS is made of, for example, silicon nitride (Si 3 N 4). The sidewall spacers SWS are formed on both side surfaces of the gate GT. In other words, the sidewall spacers SWS are formed on the first portion SRa and the first portion DRa.

The source region SR, the drain region DR, the well region WR, the gate dielectric film GI, and the gate GT constitute a transistor Tr.

The element isolation film ISL is formed in the first surface FS. More specifically, the element isolation film ISL is embedded in a trench formed in the first surface FS. The element isolation film ISL is made of, for example, silicon oxide. That is, the element isolation film ISL is a Shallow Trench Isolation (STI). The element isolation film ISL isolates the transistor Tr from the surroundings.

The pre-metal insulating film PMD is formed on the semiconductor substrate SUB (first surface FS) so as to cover the transistor Tr. The pre-metal insulating film PMD is made of, for example, silicon oxide. Contact holes are formed in the pre-metal insulating film PMD.

The contact plugs CP are electrically connected to the source regions SR and the drain regions DR, respectively. Although not shown, the contact plugs CP are also electrically connected to the gates GT. The contact plugs CP are embedded in the contact holes formed in the pre-metal insulating film PMD. The contact plug CP is made of, for example, tungsten (W).

The interlayer insulating film ILD1 is formed on the pre-metal insulating film PMD. The interlayer insulating film ILD1 is made of silicon oxide. Wiring trenches are formed in the interlayer insulating film ILD1. The wiring trenches penetrate through the interlayer insulating film ILD1 in a thickness direction.

The wirings WL1 are embedded in the wiring trenches formed in the interlayer insulating film ILD1. The wiring WL1 is made of, for example, copper or copper alloy.

The interlayer insulating film ILD2 is formed on the interlayer insulating film ILD1. The interlayer insulating film ILD2 is made of, for example, silicon oxide. Wiring trenches and via holes are formed in the interlayer insulating film ILD2. The wiring trenches are formed in a surface of the interlayer insulating film ILD2. The via holes are formed so as to penetrate through parts of the interlayer insulating film ILD2 in which the wiring trenches are formed, in a thickness direction.

The wiring WL2 has a via plug portion WL2a and a wiring portion WL2b. The via plug portion WL2a and the wiring portion WL2b are integrally formed. The via plug portion WL2a is embedded in the via hole formed in the interlayer insulating film ILD2. The wiring portion WL2b is embedded in the wiring trench formed in the interlayer insulating film. ILD2. The wiring WL2 is made of copper or copper alloy. The via plug WL2a is electrically connected to the wiring WL1. The wiring portion WL2b is electrically connected to the via plug portion WL2a included in the upper wiring layer.

The wiring layer formed of the interlayer insulating films ILD2 and the wirings WL2 is successively stacked in a direction crossing the first surface FS and the second surface SS to form a multilayer wiring structure.

The interlayer insulating film ILD3 is formed on the interlayer insulating film ILD2 included in the wiring layer farthest from the semiconductor substrate SUB. The interlayer insulating film ILD3 is made of, for example, silicon oxide. Via holes are formed in the interlayer insulating film ILD3. The via holes penetrate through the interlayer insulating film ILD3 in a thickness direction.

The via plugs VP1 and the via plugs VP2 are embedded in the via holes formed in the interlayer insulating film ILD3. The via plugs VP1 and the via plugs VP2 are made of, for example, tungsten. The via plugs VP1 and the via plugs VP2 are electrically connected to the wirings WL2 included in the wiring layer farthest from the semiconductor substrate SUB.

The bonding pads BP1 and the bonding pads BP2 are formed over the semiconductor substrate SUB. More specifically, the bonding pads BP1 and the bonding pads BP2 are formed on the interlayer insulating film ILD3.

The bonding pads BP1 are electrically connected to the via plugs VP1, and the bonding pads BP2 are electrically connected to the via plugs VP2. The bonding pads BP1 and the bonding pads BP2 are made of, for example, aluminum (Al) and aluminum alloys.

The bonding pad BP2 has a shape obtained by rotating the bonding pad BP1 by 180 degrees in plan view. That is, the bonding pad BP2 has a shape obtained by rotating the bonding pad BP1 by 180 degrees around a rotation axis orthogonal to the first surface FS. Even if the shape of the bonding pad BP2 does not strictly coincide with the shape obtained by rotating the bonding pad BP1 by 180 degrees in plan view, if the difference is within a manufacturing error, it is included in, “the bonding pad BP2 has a shape obtained by rotating the bonding pad BP1 by 180 degrees in plan view”. The bonding pad BP1 and the bonding pad BP2 are opposed to each other in the first direction DR1. The positions of both ends of the bonding pad BP1 in the second direction DR2 coincide with the positions of both ends of the bonding pad BP2 in the second direction DR2. The bonding pad BP1 is located farther from the outer peripheral side OC than the bonding pad BP2 in the first direction DR1.

The bonding pad BP1 is divided into a first portion BP1a and a second portion BP1b in the second direction DR2. That is, the first portion BP1a and the second portion BP1b are adjacent to each other in the second direction DR2. The first portion BP1a and the second portion BP1b have rectangular shapes.

The first portion BP1a has a width W1 and a width W2. The width W1 is the width of the first portion BP1a in the first direction DR1, and the width W2 is the width of the first portion BP1a in the second direction DR2.

The second portion BP1b has a width W3 and a width W4. The width W3 is the width of the second portion BP1b in the first direction DR1, and the width W4 is the width of the second portion BP1b in the second direction DR2. As will be described later, the first portion BP1a constitutes a part of the probe region, and since the probe is pressed along the first direction DR1, the width W1 is wider than the width W3 so that the probe does not protrude from the probe region. The width W4 is preferably wider than the width W2.

The side of the first portion BP1a on the bonding pad BP2 side is located closer to the outer peripheral side OC than the side of the second portion BP1b on the bonding pad BP2 side.

It is preferable that the side of the first portion BP1a on the opposite side to the bonding pad BP2 and the side of the second portion BP1b on the opposite side to the bonding pad BP2 are connected to each other. That is, it is preferable that the side of the first portion BP1a on the opposite side to the bonding pad BP2 and the side of the second portion BP1b on the opposite side to the bonding pad BP2 are on one straight line. In other words, the bonding pad BP1 and the bonding pad BP2 may have an L-shape in plan view.

The second portion BP1b is divided into a first rectangular region R1 and a second rectangular region R2 in the second direction DR2. The first rectangular region R1 and the second rectangular region R2 have rectangular shapes in plan view. The width in the first direction DR1 of the first rectangular region R1 and the second rectangular region R2 is equal to the width W 3. The first rectangular region R1 is located closer to the first portion BP1a than the second rectangular region R2. The width of the second rectangular region R2 in the second direction DR2 is the width W5. The sum of the width of the first rectangular region R1 in the second direction DR2 and the width W2 is equal to the width W5. That is, the widths of the bonding pad BP1 and the bonding pad BP2 in the second direction are equal to twice the width W5.

The first portion BP1a and the first rectangular region R1 constitute a probe region except for the portion covered with the passivating film PV. The probe region is a region in which a probe for inspection contacts. A probe mark PM is formed in the probe region. The longitudinal direction of the probe mark PM is along the first direction DR1. The second rectangular region R2 constitutes a wire bonding region except for the portion covered with the passivation film PV. The wire bonding region is a region for bonding a bonding wire.

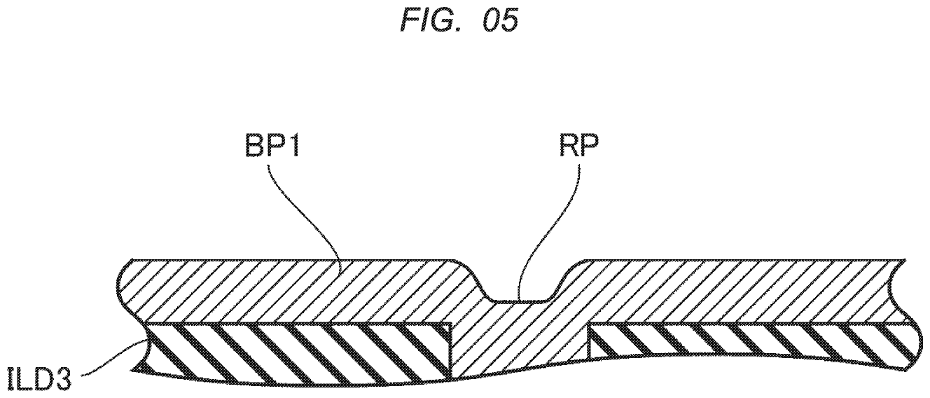

The probe region and the wire bonding region may be distinguished by, for example, concave portion RP formed on the surface of the bonding pad BP along the boundary between the probe region and the wire bonding region. As shown in FIG. 5, the surface of the bonding pad BP is recessed at the concave portion RP. The interlayer insulating film ILD3 is opened below the concave portion RP.

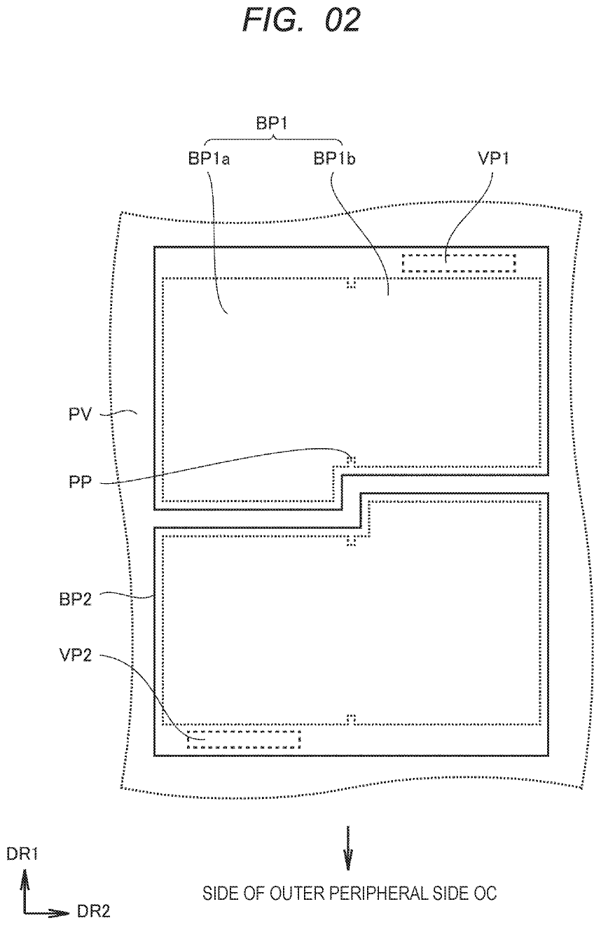

As shown in FIG. 2, the via plug VP1 is arranged so as to overlap the end of the bonding pad BP1 opposite to the bonding pad BP2 in plan view. The via plug VP2 is arranged so as to overlap the end of the bonding pad BP2 opposite to the bonding pad BP1 in plan view.

The passivating film PV is formed on the interlayer insulating film ILD3 so as to cover the peripheral portion of the bonding pad BP1 and the peripheral portion of the bonding pad BP2. That is, most of the bonding pad BP1 and the bonding pad BP2 are exposed from the opening formed in the passivating film PV. The passivation film. PV is made of, for example, silicon nitride. The protruding portion PP may be formed on the passivation film PV. The protruding portion PP is arranged at the boundary between the probe region and the wire bonding region. That is, the boundary between the probe region and the wire bonding region can be specified by checking the position of the protruding portion PP.

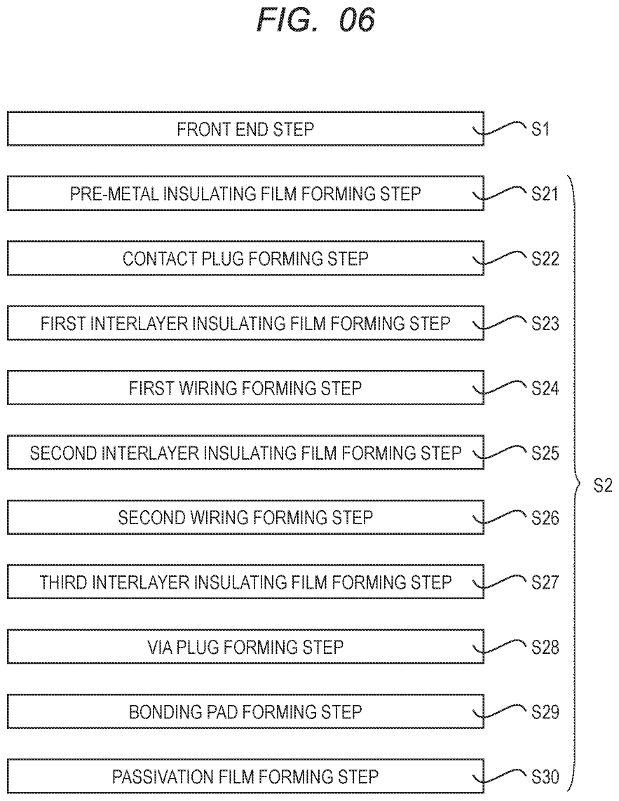

A method of manufacturing the semiconductor device according to the first embodiment will be described below. As shown in FIG. 6, the method of manufacturing the semiconductor device according to the first embodiment includes a front end step S1 and a back end step S2.

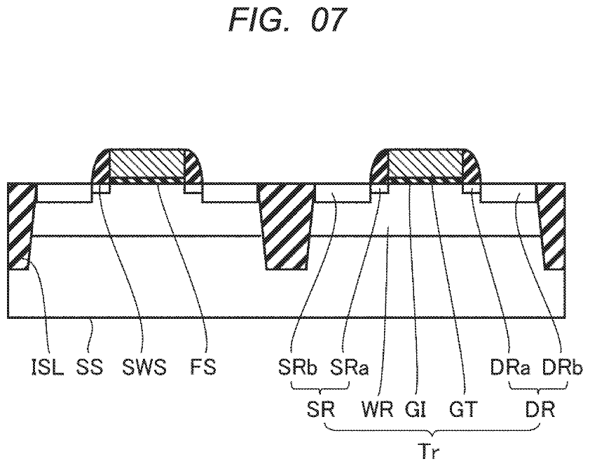

As shown in FIG. 7, in the front end step S1, source regions SR, drain regions DR, well regions WR, gate dielectric films GI, gates GT, sidewall spacers SWS, and element isolation films ISL are formed.

The source regions SR, the drain regions DR, and the well regions WR are formed by ion implantation. The gate dielectric films GI are formed by thermally oxidizing the first surface FS. The gate GT are formed by depositing materials constituting the gates GT by Chemical Vapor Deposition (CVD) or the like, and patterning the deposited materials constituting the gates GT by photolithography and etching.

The sidewall spacers SWS are formed by depositing materials constituting the sidewall spacers SWS by CVD or the like, and etching back the deposited materials constituting the sidewall spacers SWS. The element isolation films ISL are formed by embedding materials constituting the element isolation films ISL by CVD or the like in trenches formed on the first surface FS by anisotropic dry etching such as Reactive ion Etching (RIE) or the like, and removing the materials constituting the element isolation films ISL protruding from the trenches by Chemical Mechanical Polishing (CMP).

The back end step S2 includes a pre-metal insulating film forming step S21, contact plugs forming step S22, a first interlayer insulating film forming step S23, first wirings forming step S24, a second interlayer insulating film forming step S25, second wirings forming step S26, and a third interlayer insulating film forming step S27. The back end step S2 further includes via plugs forming step S28, bonding pads forming step S29, and a passivation film forming step S30.

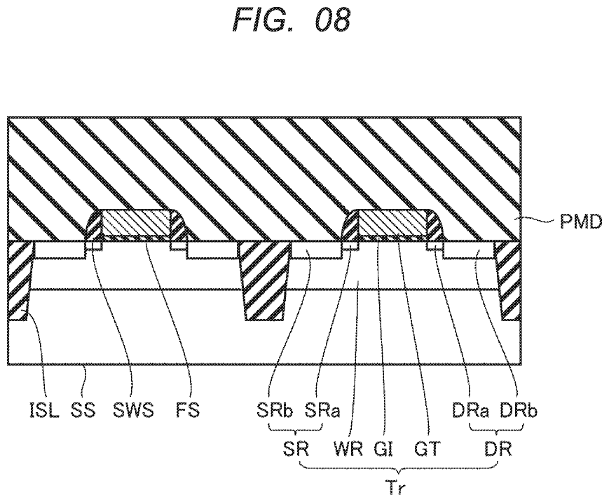

In the pre-metal insulating film forming step S21, as shown in FIG. 8, the pre-metal insulating film PMD is formed. The pre-metal insulating film PMD is formed by depositing materials constituting the pre-metal insulating film PMD by CVD or the like, and planarizing the deposited materials constituting the pre-metal insulating film PMD by CMP or the like.

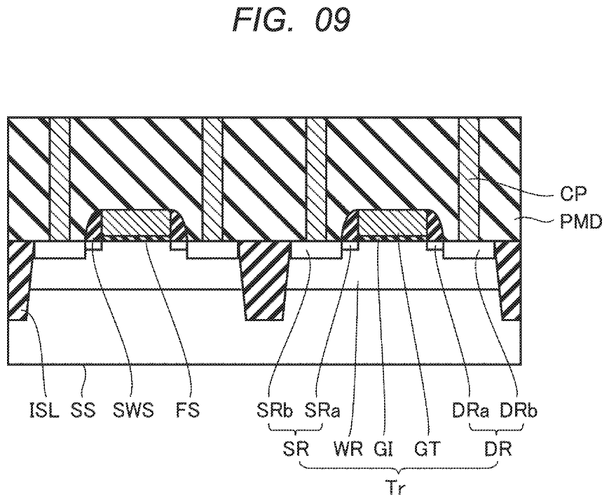

In the contact plugs forming step S22, as shown in FIG. 9, the contact plugs CP is formed. In forming the contact plugs CP, first, contact holes are formed in the pre-metal insulating film PMD by anisotropic dry etching such as RIE. In forming the contact plugs CP, second, materials constituting the contact plugs CP is embedded in the contact holes by CVD or the like. In forming the contact plugs CP, third, the materials constituting the contact plugs CP protruding from the contact holes is removed by CMP or the like.

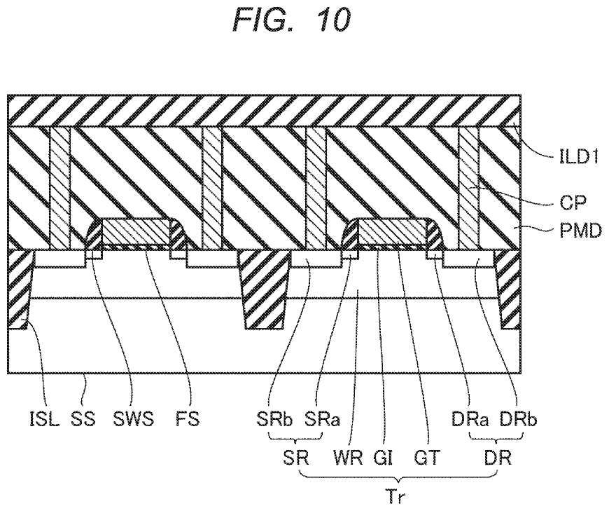

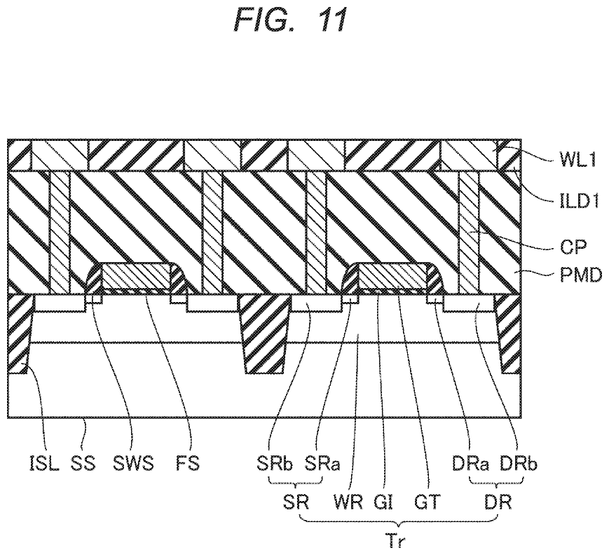

In the first interlayer insulating film forming step S23, as shown in FIG. 10, the interlayer insulating film ILD1 is formed. The interlayer insulating film ILD1 is formed, for example, by depositing materials constituting the interlayer insulating film ILD1 by CVD or the like. In the first wirings forming step S24, as shown in FIG. 11, the wirings WL1 are formed. The wirings WL1 are formed by, for example, a single damascene method.

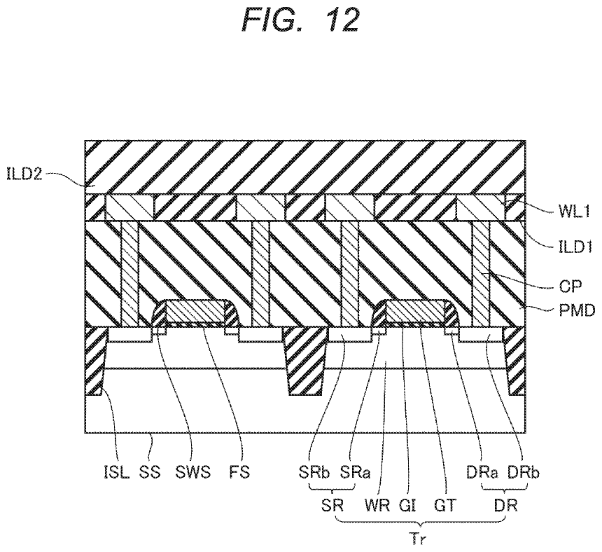

In the second interlayer insulating film forming step S25, as shown in FIG. 12, the interlayer insulating film ILD2 is formed. The interlayer insulating film ILD2 is formed by depositing materials constituting the interlayer insulating film ILD2 by, for example, CVD or the like.

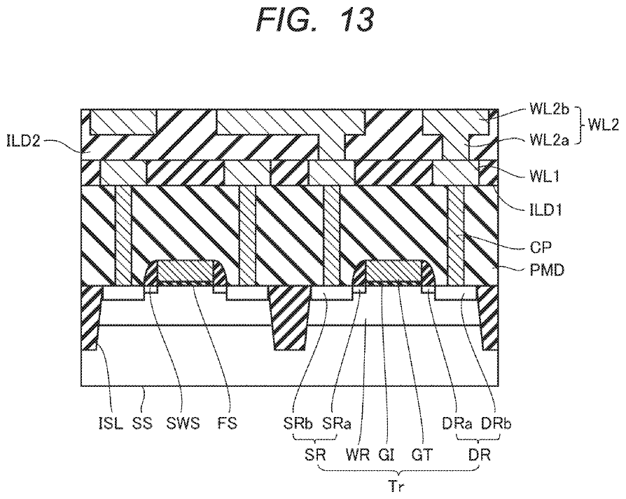

In the second wirings forming step S26, as shown in FIG. 13, the wirings WL2 are formed. The wirings WL2 are formed by, for example, a dual damascene method. The second interlayer insulating film forming step S25 and the second wirings forming step S26 are repeated a plurality of times in order to form a multilayer wiring structure.

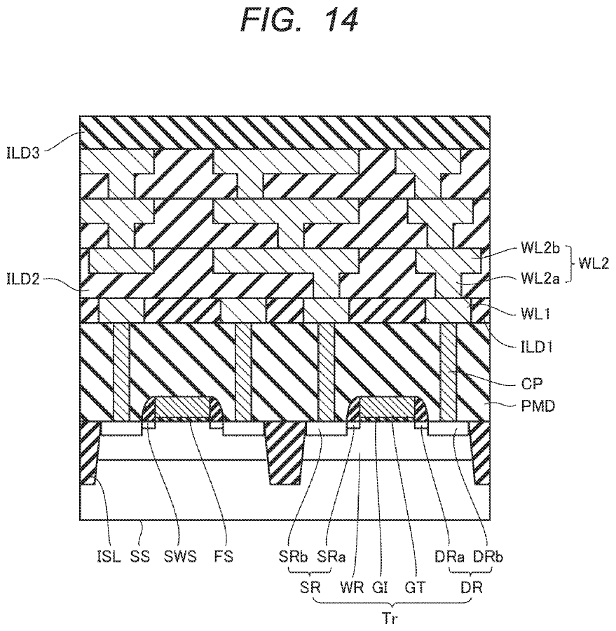

In the third interlayer insulating film forming step S27, as shown in FIG. 14, the interlayer insulating film ILD3 is formed. The interlayer insulating film ILD3 is formed by depositing materials constituting the interlayer insulating film ILD3 by, for example, CVD or the like.

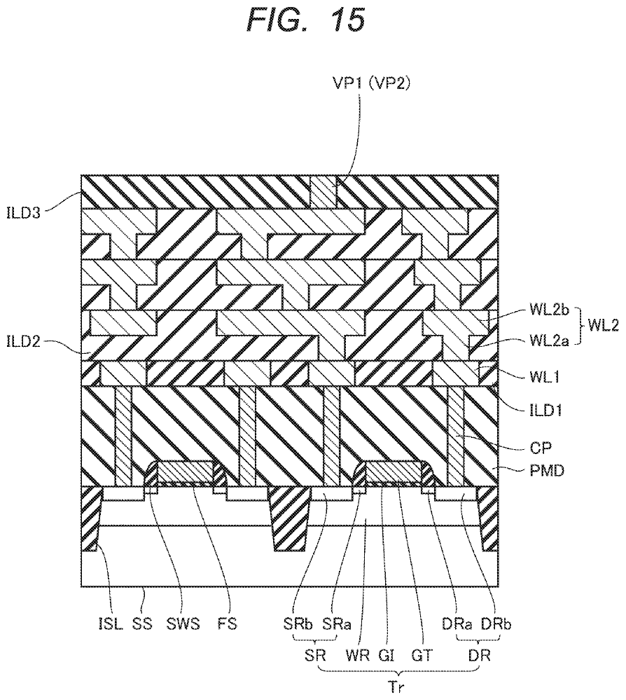

In the via plugs forming step S28, as shown in FIG. 15, the via plugs VP1 and the via plugs VP2 are formed. In forming the via plugs VP1 and the via plugs VP2, first, via holes are formed in the interlayer insulating film ILD3 by anisotropic dry etching such as RIE. In forming the via plugs VP1 and the via plugs VP2, second, materials constituting the via plugs VP1 and the via plugs VP2 are embedded in the via holes by CVD or the like. In forming the via plugs VP1 and the via plugs VP2, third, the materials constituting the via plugs VP1 and the via plugs VP2 protruding from the via holes are removed by CMP or the like.

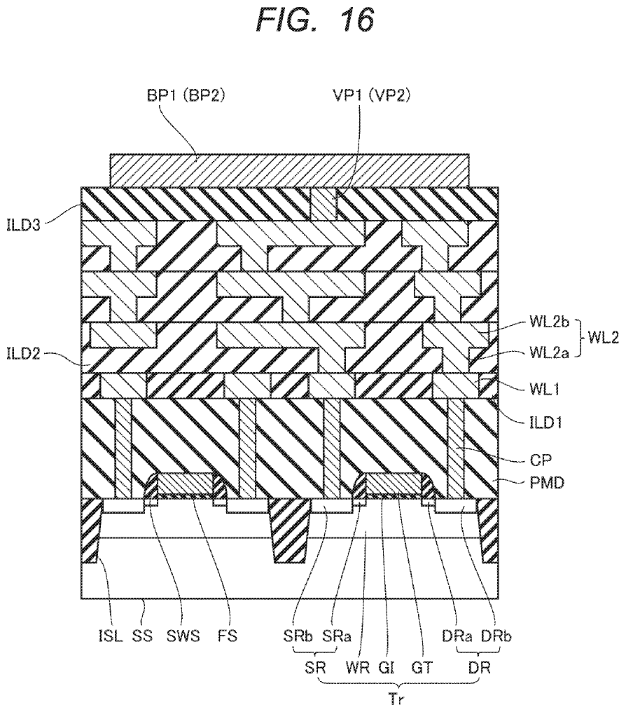

In the bonding pads forming step S29, as shown in FIG. 16, the bonding pads BP1 and the bonding pads BP2 are formed. The bonding pads BP1 and the bonding pads BP2 are formed by depositing materials constituting The bonding pads BP1 and the bonding pads BP2 by sputtering or the like, and patterning the deposited materials constituting the bonding pads BP1 and the bonding pads BP2 by photolithography and etching.

In the passivation film forming step S30, the passivation film PV is formed. The passivation film PV is formed by depositing materials constituting the passivation film PV by CVD or the like, and patterning the materials constituting the deposited passivation film PV by photolithography and etching.

As described above, the structure of the semiconductor device according to the first embodiment shown in FIGS. 1, 2, and 3 is formed. After the passivation film forming step S30 is performed, the probe marks PB are formed by performing electrical inspection on the semiconductor device according to the first embodiment.

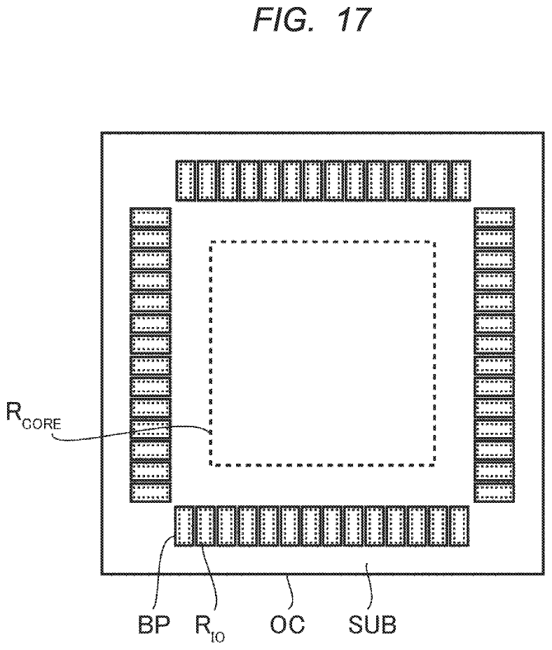

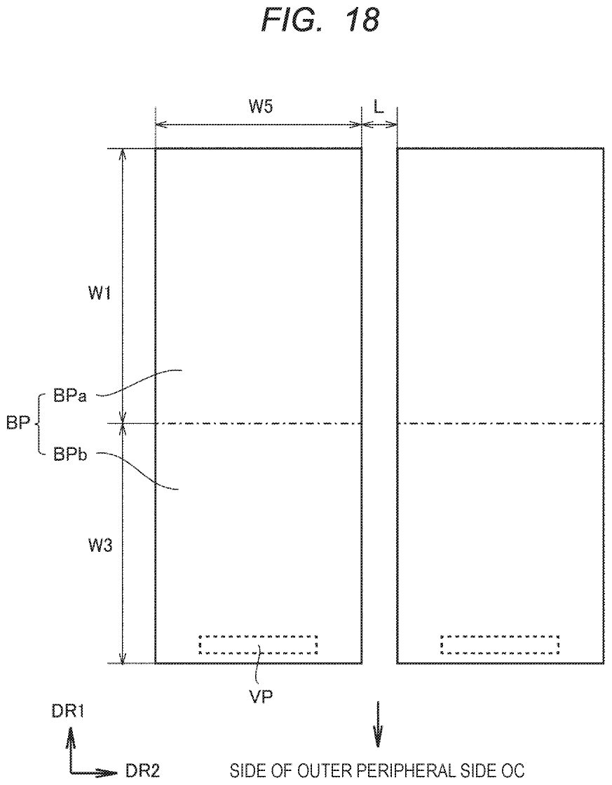

Effects of the semiconductor device according to the first embodiment will be described below in comparison with comparative example. As shown in FIGS. 17 and 18, the semiconductor device according to the comparative example is the same as the semiconductor device according to the first embodiment except that bonding pads BP are provided instead of the bonding pads BP1 and the bonding pads BP2. In the semiconductor device according to the comparative example, the via plugs VP are arranged so as to overlap the end portions of the bonding pads BP on a side of the outer peripheral sides OC in plan view.

The semiconductor substrate SUB has a core region R_{CORE} and input/output modules R_{IO}. The core region R_{CORE} is a region in which impurity diffusion regions of transistors constituting a memory circuit (Static Random Access Memory (SRAM), flash memories, or the like), and a logic circuit (Central Processing Unit (CPU)), or the like) are formed. The input/output modules R_{IO} are regions in which impurity diffusion regions of transistors constituting an input/output circuit are formed.

The core region R_{CORE} is formed in the vicinity of the center of the semiconductor substrate SUB. The input/output modules R_{IO} are formed so as to overlap the bonding pads BP in plan view. Therefore, when the widths of the bonding pads BP in the second direction DR2 is larger than the widths of the input/output modules R_{IO} in the second direction DR2, a wasteful space remains between two input/output modules R_{IO} adjacent to each other along the second direction DR2. In order to reduce such wasteful spaces as much as possible, the widths required to form the bonding pads need to be narrowed in the second direction DR2.

The bonding pad BP has a rectangular shape in plan view. The bonding pad BP is divided into a first portion BPa and a second portion BPb along the first direction DR1. The first portion BPa and the second portion BPb constitute a probe region and a wire bonding region, respectively. The first portion BPa has a width W1 in the first direction DR1. The second portion BPb has a width W3 in the first direction DR1. The first portion BPa and the second portion BPb have widths W5 in the second direction DR2.

The bonding pads BP are arranged along the second direction DR2. The distance between two bonding pads BP adjacent to each other in the second direction DR2 is the distance L. Therefore, in the semiconductor device according to the comparative example, in order to form these two bonding pads BP, a width obtained by adding the distance L to twice the width W5 in the second direction DR2 is required.

As described above, in the semiconductor device according to the first embodiment, in order to form the bonding pad BP1 and the bonding pad BP2, a width twice the width W5 in the second direction DR2 is sufficient. Therefore, according to the semiconductor device of the first embodiment, the widths required for forming the bonding pads can be narrowed in the second direction DR2.

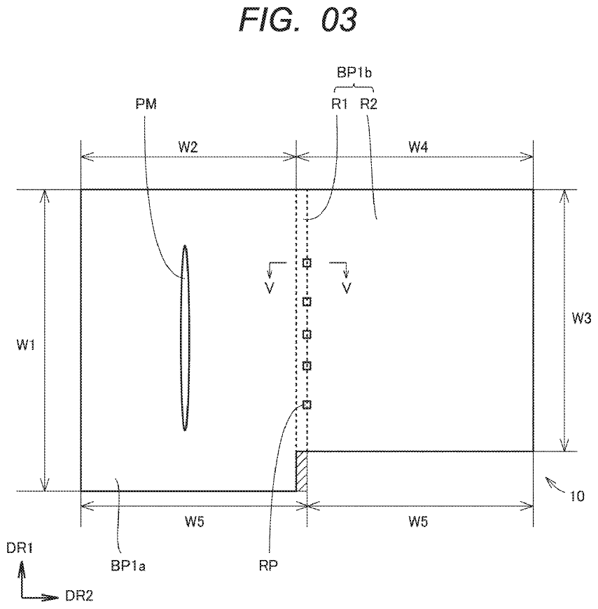

The area of the probe region in the semiconductor device according to the first embodiment is smaller than the area of the probe region in the semiconductor device according to the comparative example by the area of the region surrounded by hatching in FIG. 3. However, since the probe is pressed against the probe region along the first direction DR1, it is hardly assumed that the probe hits the region in the vicinity of the four corners of the probe region. Therefore, the reduction of the area of the probe region in the semiconductor device according to the first embodiment is not substantially problematic.

In the semiconductor device according to the first embodiment, the wire bonding region of the bonding pad BP1 and the wire bonding region of the bonding pad BP2 are arranged in a zigzag shape in plan view. Therefore, in the semiconductor device according to the first embodiment, the distances between the wire bonding regions are increased, and as a result, short-circuiting between the bonding wires is less likely to occur.

In the semiconductor device according to the first embodiment, the width W4 is larger than the width W2, and the side of the first portion BP1a on the bonding pad BP2 side is located closer to the outer peripheral side OC than the side of the second portion BP1b on the bonding pad BP2 side. Therefore, in the semiconductor device according to the first embodiment, the bonding pad BP1 and the bonding pad BP2 do not need to be arranged to be shifted along the second direction DR2. This reduces the widths required to form bonding pads in the second direction DR2. Second Embodiment

A configuration of a semiconductor device according to second embodiment will be described below. Note that differences from the configuration of the semiconductor device according to the first embodiment will be mainly described, and duplicate descriptions will not be repeated.

The semiconductor device according to the second embodiment includes a semiconductor substrate SUB, pairs of bonding pads BP1 and bonding pads BP2. The semiconductor device according to the second embodiment further includes gate dielectric films GI, gates GT, sidewall spacers SWS, element isolation films ISL, a pre-metal insulating film PMD, contact plugs CP, interlayer insulating films ILD1 to ILD3, wirings WL1 and wirings WL2, via plugs VP1, via plugs VP2, and a passivation film PV. In these respects, the configuration of the semiconductor device according to the second embodiment is the same as the configuration of the semiconductor device according to the first embodiment.

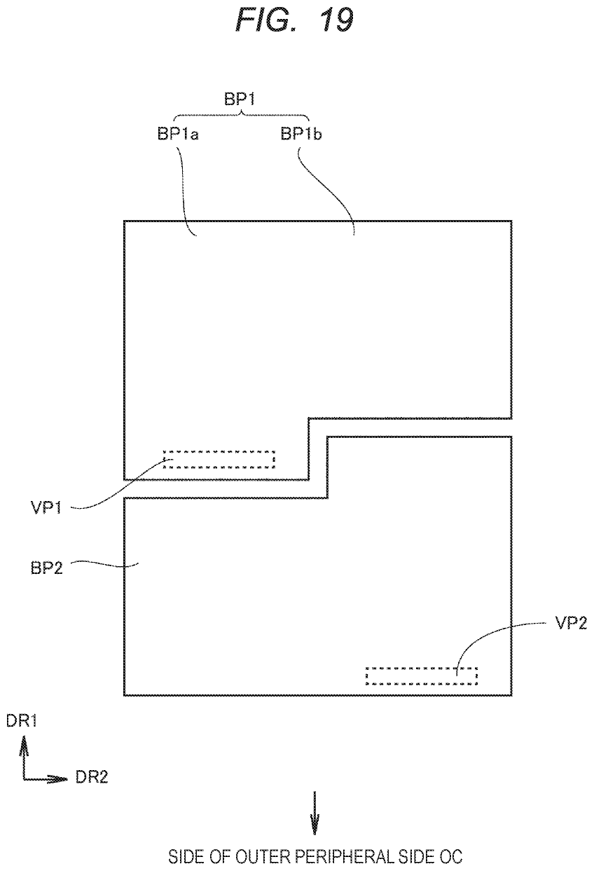

In the semiconductor device according to the second embodiment, as shown in FIG. 19, the via plug VP1 is arranged so as to overlap the end portion of the first portion BP1a on the bonding pad BP2 side in plan view. In this respect, the configuration of the semiconductor device according to the second embodiment is different from the configuration of the semiconductor device according to the first embodiment. In the semiconductor device according to the second embodiment, the bonding pads BP1 are preferably power supply pads (pads for supplying fixed voltages to transistors Tr.

A method of manufacturing the semiconductor device according to the second embodiment is the same as the method of manufacturing the semiconductor device according to the first embodiment, and therefore the explanation thereof is omitted.

Effects of the semiconductor device according to the second embodiment will be described below in comparison with comparative example. Note that differences from the effects of the semiconductor device according to the first embodiment will be mainly described, and duplicate descriptions will not be repeated.

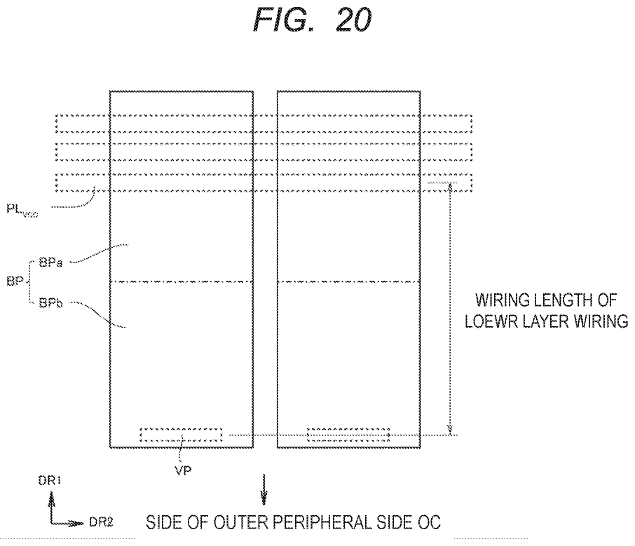

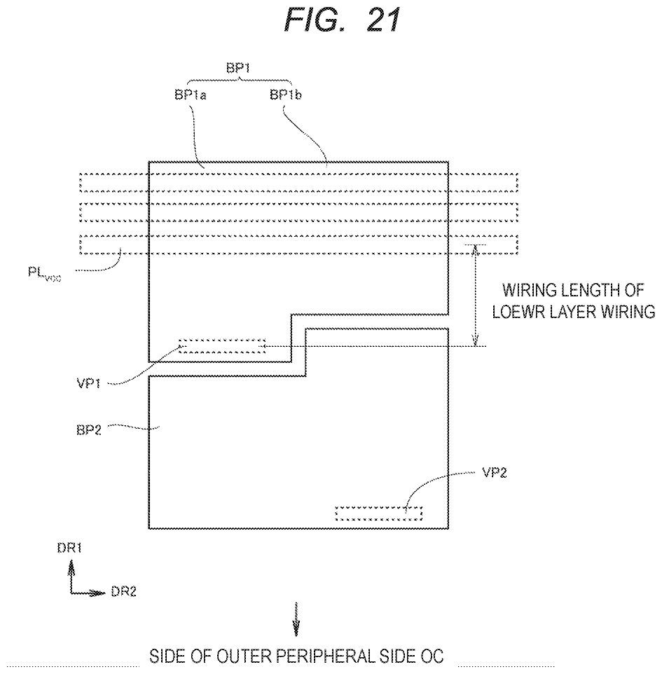

Generally, power supply wirings (only the power supply wirings PL_{VDD} for the V_{DD} are shown in FIGS. 20 and 21, but other types of power supply wirings are similarly formed) are arranged to pass below the bonding pads and circulate along the outer periphery of the semiconductor substrate SUB.

As described above, in the semiconductor device according to the comparative example, the via plugs VP are arranged so as to overlap the end portions of the bonding pads BP on a side of the outer peripheral side OC in plan view. Therefore, as shown in FIG. 20, when the via plugs VP and the power supply wirings PL_{VDD} are connected by using the lower layer wirings, the wiring lengths of the lower layer wirings become long. As a result, the voltages supplied to the transistors Tr are lower than expected by the voltages in the lower layer wirings.

On the other hand, as shown in FIG. 21, in the semiconductor device according to the second embodiment, since the via plug VP1 is arranged so as to overlap the end portion of the first portion BP1a on the bonding pad BP2 side, the wiring length of the lower layer wiring for connecting the via plug VP1 and the power supply wiring PL_{VDD} can be shortened. That is, the voltage drops in the lower layer wirings can be suppressed. In the semiconductor device according to the second embodiment, since spaces are formed in portions in which the lower layer wirings do not need to be routed, the spaces can be used to arrange wiring capacitance elements.

### Third Embodiment

A configuration of a semiconductor device according to third embodiment will be described below. Note that differences from the configuration of the semiconductor device according to the second embodiment will be mainly described, and duplicate descriptions will not be repeated.

The semiconductor device according to the third embodiment includes a semiconductor substrate SUB, pairs of bonding pads BP1 and bonding pads BP2. The semiconductor device according to the third embodiment further includes gate dielectric films GI, gates GT, sidewall spacers SWS, element isolation films ISL, a pre-metal insulating film PMD, contact plugs CP, interlayer insulating films ILD1 to ILD3, wirings WL1 and wirings WL2, via plugs VP1, via plugs VP2, and a passivation film PV.

The via plug VP1 is arranged so as to overlap the end portion of the first portion BP1a on the bonding pad BP2 side in plan view. In these respects, the configuration of the semiconductor device according to the third embodiment is the same as the configuration of the semiconductor device according to the second embodiment.

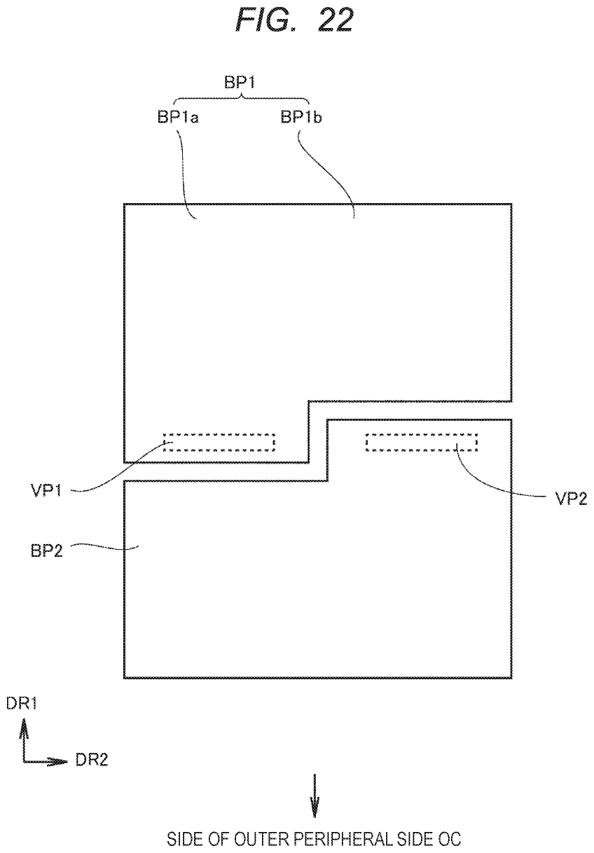

As shown in FIG. 22, in the semiconductor device according to the third embodiment, the distance between the via plug VP2 and the outer peripheral side OC in the first direction DR1 is equal to the distance between the via plug VP1 and the outer peripheral side OC in the first direction DR1. That is, in the semiconductor device according to the third embodiment, the position of the via plug VP1 in the first direction DR1 coincides with the position of the via plug VP2 in the first direction DR1. In this respect, the configuration of the semiconductor device according to the third embodiment is different from the configuration of the semiconductor device according to the second embodiment.

A method of manufacturing the semiconductor device according to the third embodiment is the same as the method of the semiconductor device according the second embodiment (method of manufacturing the semiconductor device according to the first embodiment), and therefore the explanation thereof is omitted.

Effects of the semiconductor device according to the third embodiment will be described below. Note that the differences from the effects of the semiconductor device according to the second embodiment will be mainly described, and duplicate descriptions will not be repeated.

In the semiconductor device according to the second embodiment, since the position of the via plug VP1 in the first direction DR1 does not coincide with the position of the via plug VP2 in the first direction DR1, the same input/output module R_{IO} cannot be used for the input/output module R_{IO} connected to the bonding pad BP1 and the input/output module R_{IO} connected to the bonding pad BP2. That is, two types of input/output modules R_{IO} are required. This is because the position of the impurity diffusion region included in the input/output module R_{IO} connected to the via plug changes in the input/output module R_{IO}.

On the other hand, in the semiconductor device according to the third embodiment, the position of the via plug VP1 in the first direction DR1 coincides with the position of the via plug VP2 in the first direction DR1. Therefore, in the semiconductor device according to the third embodiment, the same input/output module R_{IO} can be used for the input/output module R_{IO} connected to the bonding pad BP1 and the input/output module R_{IO} connected to the bonding pad BP2.

### Fourth Embodiment

A configuration of a semiconductor device according to fourth embodiment will be described below. Note that differences from the configuration of the semiconductor device according to the first embodiment will be mainly described, and duplicate descriptions will not be repeated.

The semiconductor device according to the fourth embodiment includes a semiconductor substrate SUB, a pair of bonding pad BP1 and a bonding pad BP2. The number of bonding pads BP1 and bonding pads BP2 to be paired is plural.

The semiconductor device according to the fourth embodiment further includes gate dielectric films GI, gates GT, sidewall spacers SWS, element isolation films ISL, a pre-metal insulating film PMD, contact plugs CP, interlayer insulating films ILD1 to ILD3, wirings WL1 and wirings WL2, via plugs VP1, via plugs VP2, and a passivation film PV. In these respects, the configuration of the semiconductor device according to the fourth embodiment is the same as the configuration of the semiconductor device according to the first embodiment.

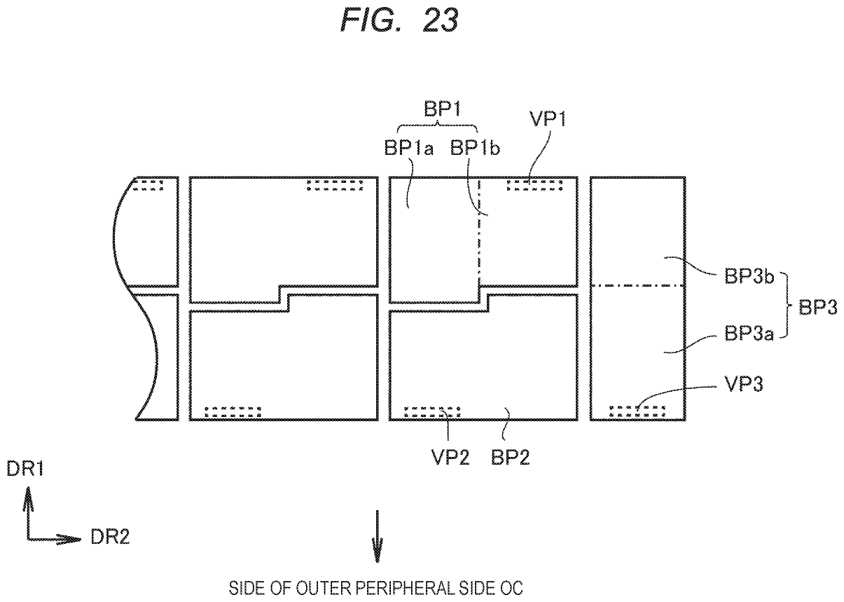

As shown in FIG. 23, the semiconductor device according to the fourth embodiment further includes a bonding pad BP3. That is, in the semiconductor device according to the fourth embodiment, the number of bonding pads is an odd number of 3 or more. The bonding pad BP3 has a rectangular shape in plan view. The width of the bonding pad BP3 in the first direction DR1 is equal to the width of the pair of the bonding pad BP1 and the bonding pad BP2 in the first direction DR1.

The bonding pad BP3 has a first portion BP3a and a second portion BP3b adjacent to each other along the first direction DR1. The first portion BP3a constitutes a probe region of the bonding pad BP3, and the second portion BP3b constitutes a wire bonding region of the bonding pad BP3.

The first portion BP3a is located farther from the outer peripheral side OC than the second portion BP3b. That is, by arranging the second portion BP3b adjacent to the second portion BP1b along the second direction DR2, the wire bonding region of the bonding pad BP1, the wire bonding region of the bonding pad BP2, and the wire bonding region of the bonding pad BP3 are arranged in a zigzag shape. In these respects, the configuration of the semiconductor device according to the fourth embodiment is different from the configuration of the semiconductor device according to the first embodiment.

The bonding pad BP3 is electrically connected to the via plug VP3. The via plug VP3 is arranged so as to overlap with the end portion of the second portion BP3b opposite to the first portion BP3a in plan view.

A method of manufacturing the semiconductor device according to the fourth embodiment is the same except that the via plug VP3 is further formed in the via plug forming step S28 and the bonding pad BP3 is further formed in the bonding pad forming step S29, and therefore detailed descriptions thereof are omitted.

Effects of the semiconductor device according to the fourth embodiment will be described below. Note that the differences from the effects of the semiconductor device according to the first embodiment will be mainly described, and duplicate descriptions will not. be repeated.

In the semiconductor device according to the fourth embodiment, even when the number of bonding pads is an odd number of three or more, the widths required for forming the bonding pads can be narrowed in the second direction DR2. In the semiconductor device according to the fourth embodiment, the width of the bonding pad BP3 in the first direction DR1 is equal to the width of the pair of the bonding pad BP1 and the bonding pad BP2 in the first. direction DR1. Therefore, it is possible to secure margins in the alignment of the wire bonding and the probe with respect to the bonding pad BP3.

### First Modification of Fourth Embodiment

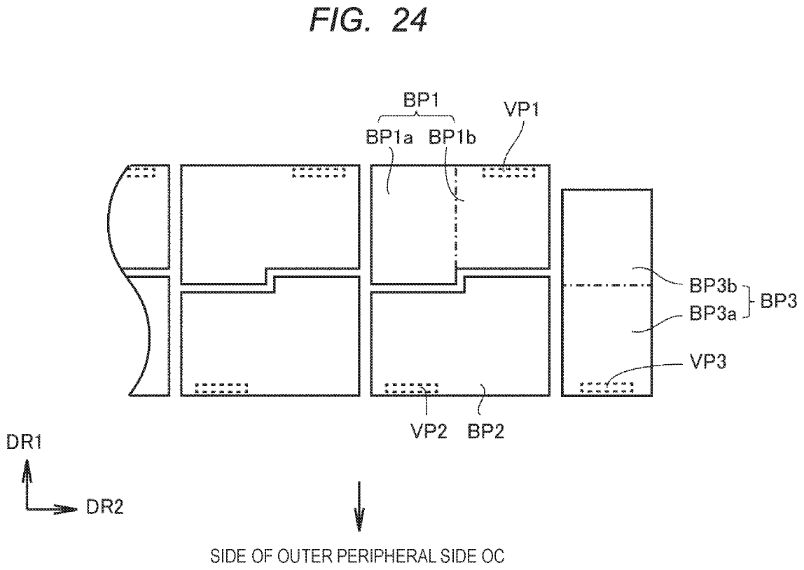

A semiconductor device according to first modification of fourth embodiment is different from the semiconductor device according to the fourth embodiment in that, as shown in FIG. 24, the width of the bonding pad BP3 in the first direction DR1 is narrower than the width of the pair of bonding pad BP1 and bonding pad BP2 in the first direction DR1.

In the transistor formed under the bonding pad and the transistor formed under the region where the bonding pad is not formed, the stress acting on the transistors change, and the transistor characteristics fluctuate. Therefore, according to the semiconductor device according to the first modification of the fourth embodiment, it is possible to widen the region where the bonding pads are not formed, and it is possible to secure a region in which transistors susceptible to stresses is arranged below the region.

### Second Modification of Fourth Embodiment

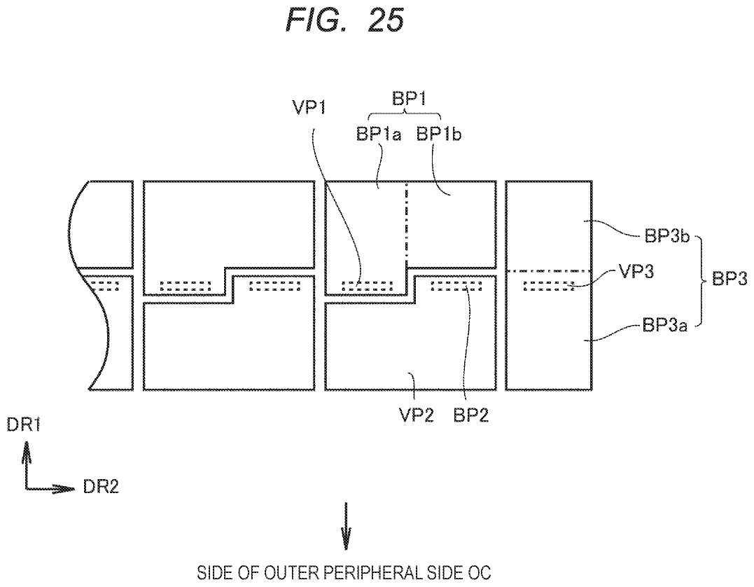

In a semiconductor device according to second modification of fourth embodiment, as shown in FIG. 25, the position of the via plug VP1 in the first direction DR1 coincides with the position of the via plug VP2 in the first direction DR1, similarly to the semiconductor device according to the third embodiment. Further, in the semiconductor device according to the second modification of the fourth embodiment, the position of the via plug VP3 in the first direction DR1 coincides with the position of the via plug VP1 in the first direction DR1 and the position of the via plug VP2 in the first direction DR1.

Therefore, a common input/output module R_{IO} can be used for the input/output module R_{IO} connected to the bonding pad BP1, the input/output module R_{IO} connected to the bonding pad BP2, and the input/output module R_{IO} connected to the bonding pad BP3.

Although the invention made by the present inventors has been specifically described based on the embodiments, the present invention is not limited to the embodiments described above, and it is needless to say that various modifications can be made without departing from the gist thereof.

What is claimed is:

1. A semiconductor device, comprising:
a semiconductor substrate having an outer peripheral side in plan view; and
a pair of first bonding pad and second bonding pad formed over the semiconductor substrate,
wherein the second bonding pad has a shape obtained by rotating the first bonding pad by 180 degrees in plan view,
wherein the first bonding pad and the second bonding pad are arranged to face each other in a first direction crossing the outer peripheral side,
wherein the first bonding pad has a first portion and a second portion of rectangular shape in a second direction along the outer peripheral side, and
wherein a width of the first portion in the first direction is larger than a width of the second portion in the first direction.

2. The semiconductor device according to claim 1,
wherein the first bonding pad is located farther from the outer peripheral side than the second bonding pad, and
wherein a side of the first portion on the second bonding pad side is located closer to the outer peripheral side than a side of the second portion on the second bonding pad side.

3. The semiconductor device according to claim 2,
wherein a side of the first portion opposite to the second bonding pad and a side of the second portion opposite to the second bonding pad are connected to each other.

4. The semiconductor device according to claim 3,
wherein a width of the second portion in the second direction is larger than a width of the first portion in the second direction.

5. The semiconductor device according to claim 4,
wherein the second portion is divided into a first rectangular region and a second rectangular region in the second direction,
wherein the first rectangular region is located on the first portion side than the second rectangular region,
wherein the first portion and the first rectangular region constitute a probe region, and
wherein the second rectangular region constitutes a wire bonding region.

6. The semiconductor device according to claim 4, further comprising:
a first via plug electrically connected to the first bonding pad,
wherein the first via plug is arranged to overlap an end portion of the first portion on the second bonding pad side in plan view.

7. The semiconductor device according to claim 6,
wherein the first bonding pad is a power supply pad.

8. The semiconductor device according to claim 7, further comprising:
a second via plug electrically connected to the second bonding pad,
wherein the second via plug is arranged such that a position of the second via plug in the first direction corresponds to a position of the first via plug in the first direction.

9. The semiconductor device according to claim 4,
wherein a plurality of the pairs of first bonding pad and second bonding pad are formed over the semiconductor substrate, and
wherein each of the plurality of the pairs of first bonding pad and second bonding pad is arranged along the second direction.

10. The semiconductor device according to claim further comprising:
a third bonding pad formed over the semiconductor substrate,
wherein the third bonding pad has a rectangular shape in plan view, and
wherein the third bonding pad is arranged adjacent the pair of first bonding pad and second bonding pad in the second direction.

11. The semiconductor device according to claim 10,
wherein a width of the third bonding pad in the first direction is equal to a width of the pair of first bonding pad and second bonding pad in the first direction.

12. The semiconductor device according to claim 10,
wherein a width of the third bonding pad in the first direction is smaller than a width of the pair of first bonding pad and second bonding pad in the first direction.

13. The semiconductor device according to claim 10, further comprising:
a first via plug electrically connected to the first bonding pad;
a second via plug electrically connected to the second bonding pad; and
a third via plug electrically connected to the third bonding pad,
wherein the first via plug is arranged to overlap an end portion of the first portion on the second bonding pad side in plan view, and
wherein a distance between the first via plug and the outer peripheral side in the first direction, a distance between the second via plug and the outer peripheral side in the first direction and a distance between the third via plug and the outer peripheral side in the first direction are equal to one another.
